(19) United States
(12) Patent Application Publication
(10) Pub. No.: US 2026/0317583 A1
(43) Pub. Date: Oct. 15, 2026

(54) RESIN COMPOSITION, ADHESIVE MEMBER, AND ELECTRONIC APPARATUS INCLUDING THE ADHESIVE MEMBER

(71) Applicant: Samsung Display Co., Ltd., Yongin-si (KR)

(72) Inventor: Koki IKUTA, Yokohama-shi (JP)

(21) Appl. No.: 19/553,851

(22) Filed: Mar. 2, 2026

(30) Foreign Application Priority Data
Apr. 14, 2025 (JP) 2025-066136

(51) Int. Cl. C09J 4/00; C08G 18/12; C09J 133/06

(52) U.S. Cl. CPC C09J 4/00; C08G 18/12; C09J 133/066

(57) ABSTRACT

A resin composition includes a urethane (meth)acrylate oligomer, and a polymer includes a unit derived from a cyclodextrin that does not have a (meth)acryloyl group.

### CROSS-REFERENCE TO RELATED APPLICATION

The present application claims priority to and the benefit of Japanese Patent Application No. 2025-066136, filed on Apr. 14, 2025, in the Japan Patent Office, the entire disclosure of which is incorporated herein by reference.

### BACKGROUND

Embodiments of the present disclosure are related to a resin composition, an adhesive member formed from the resin composition, and an electronic device including the adhesive member.

Various suitable types (kinds) of display devices used for multimedia devices such as television sets, mobile phones, tablet computers, navigation systems, and game consoles have been developed. The display devices include multiple components forming the display devices, and adhesive members are between the components. Resin compositions are provided to form the adhesive members, and the adhesive members included in the display devices are required or desired to stably bond the components of the display devices prevent or minimize degradation in display quality.

### SUMMARY

The present disclosure provides a resin composition exhibiting excellent or suitable adhesive properties, durability, impact resistance, and flexibility after curing, an adhesive member formed from the resin composition, and an electronic device including the adhesive member.

Aspects according to one or more embodiments of the present disclosure include a resin composition including a urethane (meth)acrylate oligomer, and a polymer including a unit derived from a cyclodextrin that does not have a (meth)acryloyl group.

In one or more embodiments, the polymer may include a cyclodextrin that does not have a (meth)acryloyl group or a derivative thereof.

In one or more embodiments, the cyclodextrin derivative that does not have a (meth)acryloyl group may include at least one selected from among hydroxypropyl cyclodextrin, hydroxyethyl cyclodextrin, methylated cyclodextrin, ethylated cyclodextrin, or benzylated cyclodextrin.

In one or more embodiments, the polymer may be a polyurethane in which a cyclodextrin derivative that does not have a (meth)acryloyl group is covalently bonded.

In one or more embodiments, the polymer may have a weight average molecular weight (Mw) of about 10,000 g/mol to about 100,000 g/mol.

In one or more embodiments, the polymer may be provided in an amount of about 2 wt % to about 20 wt % with respect to a total weight of the resin composition.

In one or more embodiments, the urethane (meth)acrylate oligomer may have a weight average molecular weight (Mw) of about 5,000 g/mol to about 30,000 g/mol.

In one or more embodiments, the urethane (meth)acrylate oligomer may be provided in an amount of about 2 wt % to about 20 wt % with respect to a total weight of the resin composition.

In one or more embodiments, a weight ratio of the urethane (meth)acrylate oligomer and the polymer may be about 1:0.2 to about 1:2.5.

In one or more embodiments, the resin composition may further include a monofunctional (meth)acrylate monomer.

In one or more embodiments, the monofunctional (meth)acrylate monomer may include at least one of 4-hydroxybutyl acrylate, 2-methoxyethyl acrylate, 2-hydroxyethyl acrylate, 2-hydroxypropyl acrylate, 2-hydroxybutyl acrylate, tetrahydrofurfuryl acrylate, isobornyl acrylate, 2-ethylhexyl acrylate, n-butyl acrylate, t-butyl acrylate, isodecyl acrylate, lauryl acrylate, stearyl acrylate, or isostearyl acrylate.

In one or more embodiments, the monofunctional (meth)acrylate monomer may be provided in an amount of about 60 wt % to about 95 wt % with respect to a total weight of the resin composition.

In one or more embodiments, the resin composition may further include a photopolymerization initiator.

In one or more embodiments, the photopolymerization initiator may include at least one of bis(2,4,6-trimethylbenzoyl)phenyl phosphine oxide or α-hydroxy alkyl phenone.

In one or more embodiments of the present disclosure, an adhesive member includes a polymer derived from a resin composition, wherein the resin composition includes a urethane (meth)acrylate oligomer, and a polymer including a unit derived from a cyclodextrin that does not have a (meth)acryloyl group.

In one or more embodiments, the adhesive member may have a 180° peel strength of about 600 gf/25 mm or greater on a glass substrate measured at about 25° C.

In one or more embodiments, the adhesive member may have a 180° peel strength of about 150 gf/25 mm or greater on a glass substrate measured at about 60° C.

In one or more embodiments of the present disclosure, an electronic apparatus includes a display apparatus configured to provide images, and at least one adhesive member included in the display apparatus and including a polymer derived from a resin composition, wherein the resin composition includes a urethane (meth)acrylate oligomer, and a polymer including a unit derived from a cyclodextrin that does not have a (meth)acryloyl group.

In one or more embodiments, the display apparatus may further include a display panel configured to display images and a window on the display panel, and the adhesive member may be between the display panel and the window.

In one or more embodiments, the window may include a base layer and a printing layer between the adhesive member and the base layer, and the resin composition provided on one surface of the display panel or one surface of the window may be cured by light passing through the printing layer for irradiation to form the adhesive member.

In one or more embodiments, the electronic apparatus may be a television, a monitor, an outdoor billboard, a personal computer, a laptop computer, a personal digital terminal, an in-vehicle device, a game console, a smartphone, a tablet, a smartwatch, or a camera.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a block diagram of an electronic device according to one or more embodiments;

FIG. 2 shows schematic views of electronic devices according to one or more suitable embodiments;

FIG. 3 is a perspective view showing an electronic device according to one or more embodiments;

FIG. 4 is an exploded perspective view showing a display device according to one or more embodiments;

FIG. 5 is a cross-sectional view showing a portion corresponding to line I-I′ of FIG. 4;

FIG. 6 is a cross-sectional view showing a portion of a display device according to one or more embodiments;

FIG. 7A is a view showing a method for preparing an adhesive member according to one or more embodiments;

FIG. 7B is a view showing a method for preparing an adhesive member according to one or more embodiments;

FIG. 7C is a view showing a method for preparing an adhesive member according to one or more embodiments;

FIG. 7D is a view showing a method for preparing an adhesive member according to one or more embodiments;

FIG. 8A is a view showing a method for preparing an adhesive member according to one or more embodiments;

FIG. 8B is a view showing a method for preparing an adhesive member according to one or more embodiments;

FIG. 8C is a view showing a method for preparing an adhesive member according to one or more embodiments;

FIG. 9 is a cross-sectional view showing a display device according to one or more embodiments;

FIG. 10 is a cross-sectional view showing a display device according to one or more embodiments;

FIG. 11A is a perspective view showing an electronic device according to one or more embodiments;

FIG. 11B is a perspective view showing an electronic device according to one or more embodiments;

FIG. 11C is a plan view showing an electronic device according to one or

more embodiments; and

FIG. 11D is a perspective view showing an electronic device according to one or more embodiments.

### DETAILED DESCRIPTION

The present disclosure may be modified in many alternate forms, and thus specific embodiments will be exemplified in the drawings and described in more detail in the text. It should be understood, however, that it is not intended to limit the present disclosure to the particular forms disclosed, but rather, is intended to cover all modifications, equivalents, and alternatives falling within the spirit and scope of the present disclosure.

In this disclosure, it will be understood that when an element (or a region, a layer, a portion, or the like) is referred to as being “on”, “connected to” or “coupled to” another element, it may be directly arranged on, connected to, or coupled to the other element, or other elements may be arranged therebetween.

All numbers and expressions related to the quantities of components, reaction conditions, and the like used herein are to be understood as being modified by the term “about”, unless otherwise indicated.

Like reference numerals or symbols refer to like elements throughout. In the drawings, the thickness, ratio, and size of the elements may be exaggerated for effectively describing the technical contents. The term “and/or” includes any and all combinations of one or more of the associated listed elements.

It will be understood that, although the terms “first”, “second”, and/or the like may be used herein to describe one or more suitable elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present disclosure. Similarly, a second element, component, region, layer or section could be termed a first element, component, region, layer or section. The singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this disclosure, specify the presence of stated features, numbers, steps, operations, elements, components and/or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a resin composition according to one or more embodiments of the present disclosure, an adhesive member according to one or more embodiments, and an electronic device including the same will be described. A display device according to one or more embodiments may be applied to one or more suitable electronic devices. An electronic device according to one or more embodiments may include a display device, and may further include a module or a device having additional functions in addition to the display device.

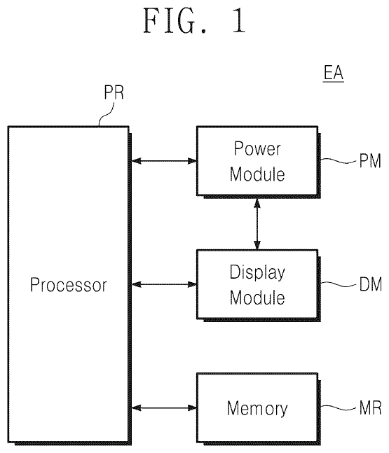

FIG. 1 is a block diagram of an electronic device according to one or more embodiments. Referring to FIG. 1, an electronic device EA according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data and/or information required for the operation of the processor PR or the display module DM. When the processor PR executes an application stored in the memory MR, image data signals and/or input control signals are transmitted to the display module DM, and the display module DM may process the received signal and output image information through a display screen.

The power module PM may include a power supply module, such as a power adapter or a battery device, and a power conversion module that converts power supplied by the power supply module to generate power required for the operation of the electronic device EA.

At least one of the components of the electronic device EA described above may be included in the display device according to the embodiments described below. For example, some of the individual modules functionally included in one module may be included in the display device, and others may be separately provided from the display device. For example, the display device may include a display module DM, and the processor PR, the memory MR, and the power module PM may be provided in the form of other devices within the electronic device EA, rather than the display device.

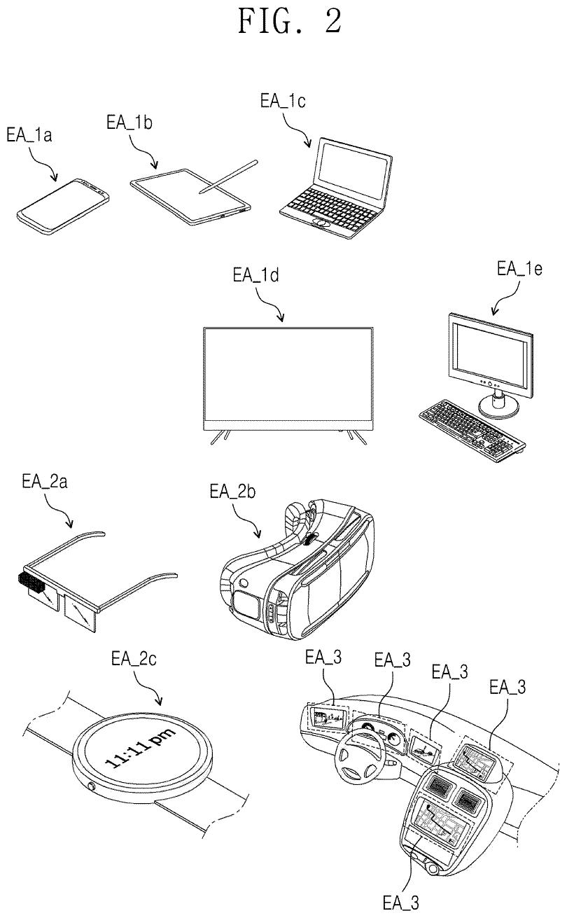

FIG. 2 shows schematic views of electronic devices according to one or more suitable embodiments. Referring to FIG. 2, one or more suitable electronic devices to which the display device according to one or more embodiments is applied may include an electronic device for displaying images, such as a smart phone EA_1a, a tablet PC EA_1b, a laptop EA_1c, a TV EA_1d, and a desk monitor EA_1e, a wearable electronic device including a display module such as a smart glasses EA_2a, a head mounted display EA_2b, and a smart watch EA_2c, and a vehicle electronic device EA_3 including a display module such as a center information display (CID) and a room mirror display on an instrument panel, a center fascia, or a dashboard of a vehicle.

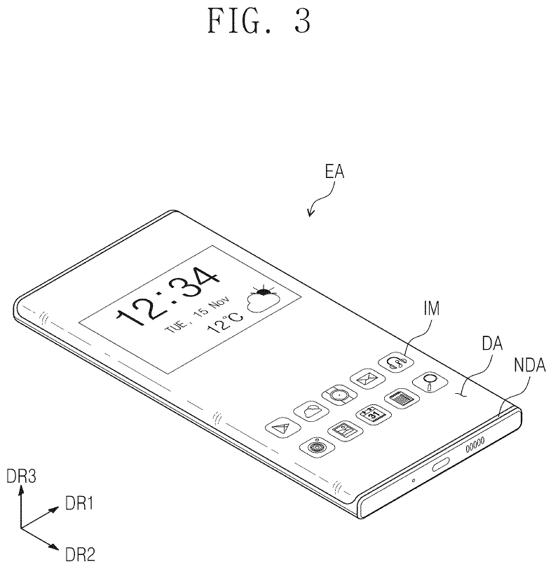

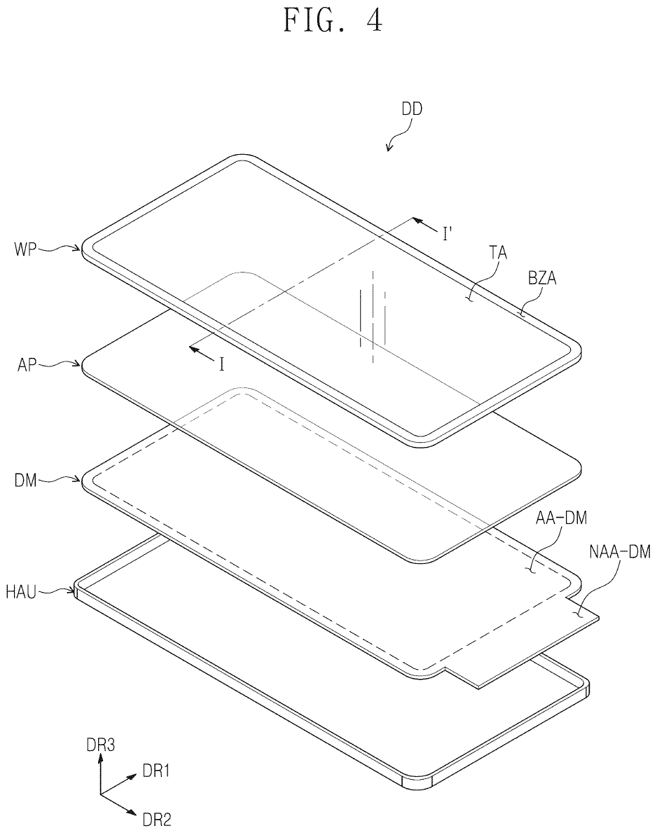

FIG. 3 is a perspective view showing an electronic device according to one or more embodiments. FIG. 4 is an exploded perspective view of a display device according to one or more embodiments.

An electronic device EA according to one or more embodiments shown in FIG. 3 may be a device activated according to electrical signals. In FIG. 3, a smartphone is shown as the electronic device EA by way of example.

The electronic device EA according to one or more embodiments may display an image IM through a display region DA. The display region DA may include a plane defined by the first directional axis DR1 and the second directional axis DR2. The display region DA may further include a curved surface bent from one side of the plane defined by the first directional axis DR1 and the second directional axis DR2.

The electronic device EA according to one or more embodiments shown in FIG. 3 is shown to include two curved surfaces each bent from both sides of the plane defined by the first directional axis DR1 and the second directional axis DR2. However, the shape of the display region DA is not limited thereto. For example, the display region DA may include only the plane defined by the first directional axis DR1 and the second directional axis DR2, and the display region DA may further include curved surfaces each bent from at least two sides of the plane defined by the first directional axis DR1 and the second directional axis DR2 (e.g., four curved surfaces each bent from four sides of the plane).

The electronic device EA according to one or more embodiments may be flexible. The term “flexible” indicates a property of being bendable, and may encompass various degrees of bendability from a completely foldable structure to a structure bendable to a several-nanometer degree. For example, the electronic device EA may be a foldable electronic device. In one or more embodiments, the electronic device EA may be rigid.

The non-display region NDA may be a region adjacent to the display region DA. The non-display region NDA may surround the display region DA. Accordingly, the shape of the display region DA may be defined substantially by the non-display region NDA. However, this is presented as an example, and the non-display region NDA may be adjacent to only one side of the display region DA, or may not be provided. The display region DA may be provided in various suitable shapes and is not limited to the embodiments.

FIG. 3 and the following drawings show first to third directional axes DR1 to DR3, and directions indicated by the first to third directional axes DR1, DR2, and DR3 described herein are relative concepts, and may thus be changed to other directions. For example, the directions indicated by the first to third directional axes DR1, DR2, and DR3 may be described as first to third directions, and the same reference numerals may be used. The first directional axis DR1 and the second directional axis DR2 herein may be perpendicular to each other, and the third directional axis DR3 may be a normal direction with respect to a plane defined by the first directional axis DR1 and the second directional axis DR2.

A thickness direction of the electronic device EA may be parallel to the third directional axis DR3 which is a normal direction with respect to a plane defined by the first directional axis DR1 and the second directional axis DR2. As described herein, a front surface (or an upper surface, upper portion surface, upper side) and a rear surface (or a lower surface, lower portion surface, lower side) of members constituting the electronic device EA may be defined with respect to the third directional axis DR3. For example, a direction in which the third directional axis DR3 extends is parallel to the thickness direction, and the front surface (or an upper surface, upper portion surface, upper side) indicates a surface (or direction) adjacent to a surface on which the image IM is displayed, and the rear surface (or a lower surface, lower portion surface, lower side) indicates a surface (or direction) spaced apart from a surface on which the image IM is displayed. Herein, the term ‘plane’ refers to a plane parallel to the plane defined by the first directional axis DR1 and the second directional axis DR2, and the term ‘cross-section’ refers to a plane perpendicular to the plane defined by the first directional axis DR1 and the second directional axis DR2 and parallel to the thickness direction DR3.

FIG. 4 is an exploded perspective view of a display device according to one or more embodiments. The display device DD according to one or more embodiments shown in FIG. 4 may be included in the electronic device ED according to one or more embodiments shown in FIG. 3.

Referring to FIG. 4, the display device DD according to one or more embodiments may include a display module DM, a window WP on the display module DM, and an adhesive member AP between the display module DM and the window WP. For example, the display device DD may further include a housing HAU accommodating the display module DM.

In the display device DD shown in FIG. 4, the window WP and the housing HAU may be bonded together to form an outer portion of the display device DD. The housing HAU may be below the display module DM. The housing HAU may include a material having a relatively greater rigidity. For example, the housing HAU may include a plurality of frames and/or plates formed of glass, plastic, or metal. The housing HAU may provide a place for accommodation. The display module DM may be accommodated in the accommodation space so as to be protected from an external impact.

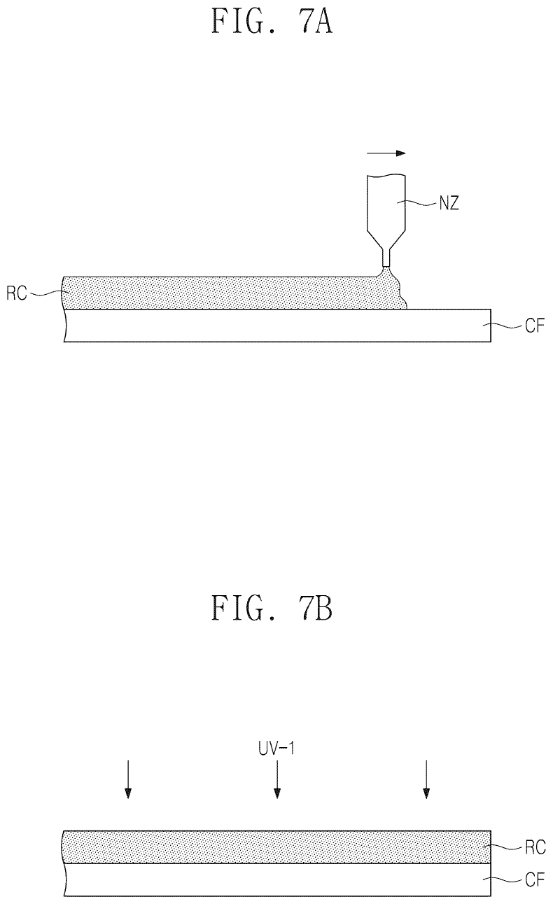

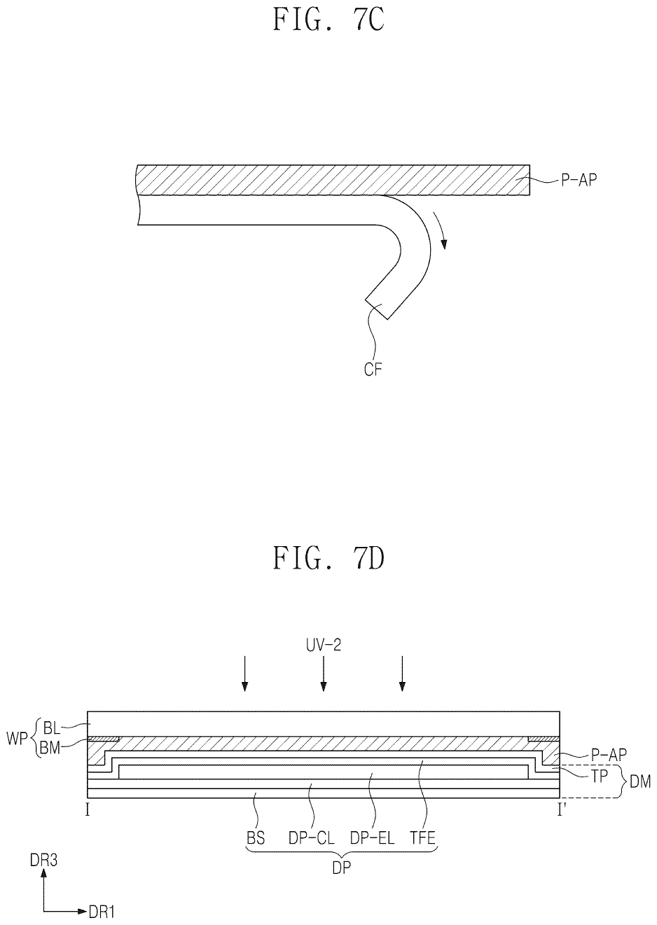

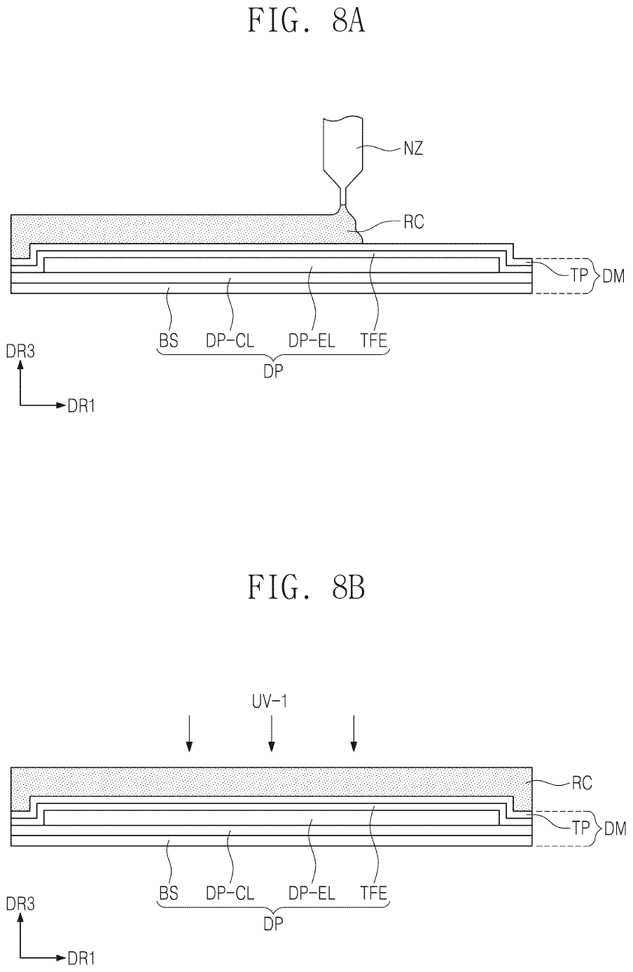

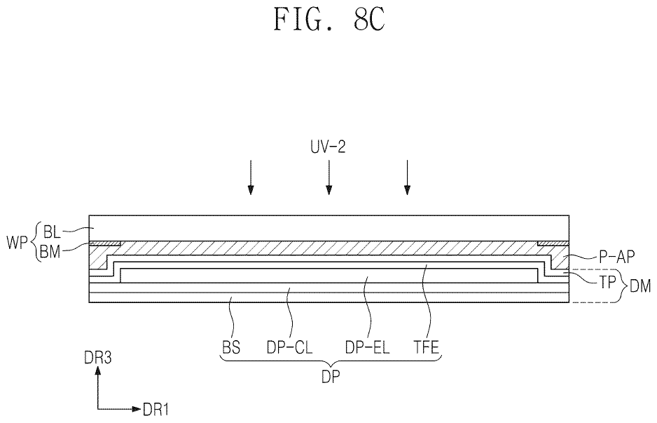

In one or more embodiments, the adhesive member AP may include a polymer derived from a resin composition RC (FIGS. 7A and 8A). The adhesive member AP may be formed by photo-curing the resin composition RC (FIGS. 7A and 8A). The display module DM and the window WP may be bonded through the adhesive member AP. The adhesive member AP according to one or more embodiments is formed from the resin composition RC (FIGS. 7A and 8A) according to one or more embodiments, and may thus exhibit excellent adhesive reliability. For example, in one or more embodiments, the adhesive member AP may be prevented from discoloration caused by external light (e.g., UV light).

The window WP may include a transmission region TA and a bezel region BZA. The transmission region TA may overlap at least a portion of the active region AA-DM of the display module DM. The transmission region TA may be an optically transparent region. The image IM (FIG. 3) may be provided to users through the transmission region TA.

The bezel region BZA may be a region having a relatively lower light transmittance than the transmission region TA. The bezel region BZA may define a shape of the transmission region TA. The bezel region BZA may be adjacent to the transmission region TA and may surround the transmission region TA.

The bezel region BZA may have a color. The bezel region BZA covers the peripheral region NAA-DM of the display module DM, and may thus prevent the peripheral region NAA-DM from being viewed from the outside. However, embodiments are not limited to what is shown, and the bezel region BZA may be adjacent to only one side of the transmission region TA, and at least a portion thereof may not be provided.

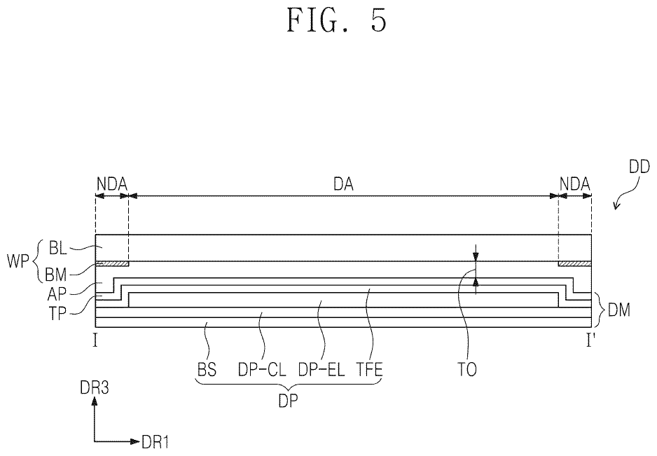

FIG. 5 is a cross-sectional view showing a portion corresponding to line I-I′ of FIG. 4; FIG. 5 is a cross-sectional view showing a display device according to one or more embodiments including the display module DM, the adhesive member AP, and the window WP of FIG. 4.

Referring to FIG. 5, the display module DM may include a display panel DP and an input sensing portion TP on the display panel DP. The display panel DP may be configured to substantially generate images. The display panel DP may include a base substrate BS, a circuit layer DP-CL on the base substrate BS, a display element layer DP-EL on the circuit layer DP-CL, and an encapsulation layer TFE covering the display element layer DP-EL. The adhesive member AP may be between the display module DM and the window WP. When the display module DM includes the display panel DP and the input sensing portion TP, an adhesive member AP may be between the input sensing portion TP and the window WP on the display panel DP.

The components of the display panel DP shown in FIG. 5 are an example and the components of the display panel DP are not limited thereto. For example, the display panel DP may include a liquid crystal display element, and in this case, the encapsulation layer TFE may not be provided.

The base substrate BS may provide a base surface on which the circuit layer DP-CL is arranged. The base substrate BS may be a flexible substrate that is bendable, foldable, rollable, and/or the like. The base substrate BS may be a glass substrate, a metal substrate, or a polymer substrate. However, the embodiments are not limited thereto, and the base substrate BS may be an inorganic layer, an organic layer, or a composite material layer including an inorganic layer and an organic layer.

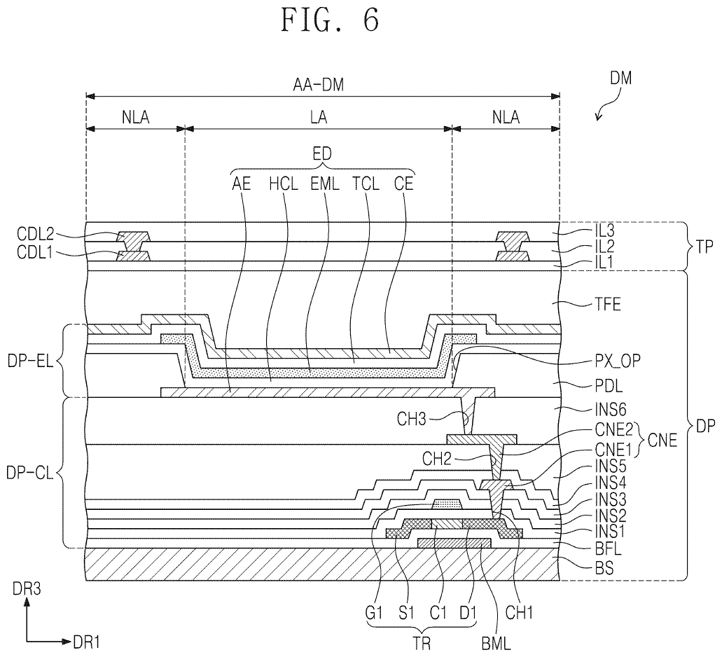

The circuit layer DP-CL may include an insulating layer, a semiconductor pattern, a conductive pattern, a signal line, and/or the like. For example, the circuit layer DP-CL may include a switching transistor and a driving transistor for driving a light emitting element ED (FIG. 6) of the display element layer DP-EL.

The display element layer DP-EL may include the light emitting element (FIG. 6) emitting light. For example, the light emitting element (FIG. 6) may include organic light emitting materials, inorganic light emitting materials, organic-inorganic light emitting materials, quantum dots, quantum rods, micro LEDs, or nano LEDs.

The encapsulation layer TFE may be on the display element layer DP-EL. The encapsulation layer TFE may serve to protect the light emitting element layer DP-EL from moisture, oxygen, and/or foreign substances, such as dust particles. The encapsulation layer TFE may include at least one inorganic layer. For example, the encapsulation layer TFE may include an inorganic layer, an organic layer, and an inorganic layer, which are sequentially stacked.

The input sensing portion TP may be on the display panel DP. For example, the input sensing portion TP may be directly on the encapsulation layer TFE of the display panel DP. Alternatively, an adhesive layer may be between the input sensing portion TP and the display panel DP.

In one or more embodiments, when a component is directly arranged/provided on another component, it indicates that a third component is not arranged/provided between one component and another component. For example, when a component is ‘directly arranged/provided’ on another component, it indicates that a component is in ‘contact’ with another component.

The input sensing portion TP may sense external inputs to convert the inputs into input signals, and provide the input signals to the display panel DP. For example, in the display device DD according to one or more embodiments, the input sensing portion TP may be a touch sensing portion sensing a touch. The input sensing portion TP may recognize a user's direct touch, a user's indirect touch, a direct touch of an object, or an indirect touch of an object.

The input sensing portion TP may sense a location of a touch or strength (pressure) of a touch applied from the outside. In one or more embodiments, the input sensing portion TP may have various suitable structures or be formed of various suitable materials, and is not limited to the embodiments. For example, the input sensing portion TP may sense external inputs using a capacitive method. The display panel DP may receive input signals from the input sensing portion TP and generate images corresponding to the input signals.

The window WP may include a base layer BL and a printing layer BM. Although not shown, the window WP may further include at least one functional layer provided on the base layer BL. For example, the functional layer may be a hard coating layer, an anti-fingerprint coating layer, and/or the like, but embodiments are not limited thereto.

The base layer BL may be a glass substrate. Alternatively, the base layer BL may be a plastic substrate. For example, the base layer BL may be formed of polyimide, polyacrylate, polymethylmethacrylate, polycarbonate, polyethylenenaphthalate, polyvinylidene chloride, polyvinylidene difluoride, polystyrene, ethylene vinylalcohol copolymer, and/or a combination thereof.

The printing layer BM may be on one surface of the base layer BL. The printing layer BM may be provided on a lower surface of the base layer BL adjacent to the display module DM. The printing layer BM may be on an edge region of the base layer BL. The printing layer BM may be an ink printing layer. For example, the printing layer BM may be a layer formed by including pigment or dye. The printing layer BM may be formed including a light absorbing material, or may be formed including a black pigment or a black dye. However, this is presented as an example, and embodiments are not limited thereto. In the window WP, the bezel region BZA (FIG. 4) may be a portion in which the printing layer BM is provided.

The adhesive member AP may have a thickness range (T0) of about 50 μm to about 300 μm. For example, the adhesive member AP may have a thickness range (T0) of about 50 μm to about 250 μm. However, this is presented as an example, and the thickness (T0) of the adhesive member AP is not limited thereto.

FIG. 6 is a cross-sectional view specifically showing the display module DM of FIG. 5. Components of the display module DM shown in FIG. 6 are presented as an example, and embodiments are not limited thereto.

In FIG. 6, the base substrate BS may include a single layer or multiple layers. For example, the base substrate BS may include a first synthetic resin layer, a multi- or single-layered inorganic layer, and a second synthetic resin layer on the multi- or single-layered inorganic layer. Each of the first synthetic resin layer and the second synthetic resin layer may include a polyimide-based resin. For example, each of the first synthetic resin layer and the second synthetic resin layer may include at least one selected from among an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. Herein, a “~~ based” resin may be considered as including a functional group of “~~”.

The display panel DP may include a transistor TR and a light emitting element ED. The transistor TR and the light emitting element ED may be on the base substrate BS. Although one transistor TR is shown in FIG. 6, the display panel DP may include a plurality of transistors and at least one capacitor for driving the light emitting element ED.

The circuit layer DP-CL may be on the base substrate BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stack structure of the circuit layer DP-CL shown in FIG. 6 is presented as an example, and the stack structure of the circuit layer DP-CL may change depending on components of the display panel DP and processes of the circuit layer DP-CL.

The shielding electrode BML may be on the base substrate BS. The shielding electrode BML may overlap the transistor TR. The shielding electrode BML may protect the transistor TR by blocking light incident on the transistor TR from a lower portion of the display panel DP. The shielding electrode BML may include a conductive material. When a voltage is applied to the shielding electrode BML, threshold voltage of the transistor TR on the shielding electrode BML may be maintained. However, embodiments are not limited thereto, and the shielding electrode BML may be a floating electrode. The shielding electrode BML may not be provided.

The buffer layer BFL may be on the base substrate BS to cover the shielding electrode BML. The buffer layer BFL may include an inorganic layer. The buffer layer BFL may improve the bonding force between the base substrate BS and a semiconductor pattern or a conductive pattern on the buffer layer BFL.

The transistor TR may include a source S1, a channel C1, a drain D1, and a gate G1. The source S1, the channel C1, and the drain D of the transistor TR may be formed from the semiconductor pattern. The semiconductor pattern of the transistor TR may include polysilicon, amorphous silicon, or metal oxide, and may be applied without limitation as long as it has semiconductor properties.

The semiconductor pattern may include a plurality of regions divided according to the level of conductivity. In the semiconductor pattern, a region doped with a dopant or reduced with metal oxide may have high conductivity and may substantially serve as a source electrode and a drain electrode of the transistor TR. The region having high conductivity in the semiconductor pattern may correspond to the source S1 and the drain D1 of the transistor TR. In the semiconductor pattern, a region undoped, doped at a low concentration, or non-reduced with metal oxide, thereby having low conductivity, may correspond to the channel C1 (or active) of the transistor TR.

The first insulating layer INS1 may cover the semiconductor pattern of the transistor TR and be on the buffer layer BFL. The gate G1 of the transistor TR may be on the first insulating layer INS1. When viewed on a plane, the gate G1 may overlap the channel C1 of the transistor TR. The gate G1 may serve as a mask in the process of doping the semiconductor pattern of the transistor TR.

The second insulating layer INS2 may cover the gate G1 and be on the first insulating layer INS1. The third insulating layer INS3 may be on the second insulating layer INS2.

The connection electrode CNE may include a first connection electrode CNE1 and a second connection electrode CNE2 to electrically connect the transistor TR and the light emitting element ED. However, the components of the connection electrode CNE that electrically connect the transistor TR and the light emitting element ED is not limited thereto, and one of the first and second connection electrodes CNE1 and CNE2 may not be provided or an additional connection electrode may be further included.

The first connection electrode CNE1 may be on the third insulating layer INS3. The first connection electrode CNE1 may be connected to the drain D1 through a first contact hole CH1 passing through the first to third insulating layers INS1 to INS3. The fourth insulating layer INS4 may cover the first connection electrode CNE1 and be on the third insulating layer INS3. The fifth insulating layer INS5 may be on the fourth insulating layer INS4.

The second connection electrode CNE2 may be on the fifth insulating layer INS5. The second connection electrode CNE2 may be connected to the first connection electrode CNE1 through a second contact hole CH2 passing through the fourth and fifth insulating layers INS4 and INS5. The sixth insulating layer INS6 may cover the second connection electrode CNE2 and be on the fifth insulating layer INS5.

The first to sixth insulating layers INS1 to INS6 may each include an inorganic layer or an organic layer. For example, the inorganic layer may include at least one selected from among aluminum oxide, titanium oxide, silicon oxide, silicon oxynitride, zirconium oxide, or hafnium oxide. The organic layer may include at least any one selected from among an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-EL may include a pixel defining film PDL and a light emitting element ED. The light emitting element ED may include a first electrode AE, a hole control layer HCL, an emission layer EML, an electron control layer TCL, and a second electrode CE.

The first electrode AE may be on the sixth insulating layer INS6. The first electrode AE may be connected to the second connection electrode CNE2 through a third contact hole CH3 passing through the sixth insulating layer INS6. The first electrode AE may be electrically connected to the drain D1 of the transistor TR through the first and second connection electrodes CNE1 and CNE2.

The first electrode AE may be formed of a metal material, a metal alloy, or a conductive compound. The first electrode AE may be an anode or a cathode. For example, the first electrode AE may be a pixel electrode. The first electrode AE may be a transmissive electrode, a transflective electrode, or a reflective electrode. The first electrode AE may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof.

When the first electrode AE is a transmissive electrode, the first electrode AE may include a transparent metal oxide, such as indium tin oxide (ITO), indium zinc oxide (IZO), zinc oxide (ZnO), and indium tin zinc oxide (ITZO). When the first electrode AE is a transflective electrode or a reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, or a compound or mixture thereof (e.g., a mixture of Ag and Mg). Alternatively, the first electrode AE may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the first electrode AE may have a three-layer structure of ITO/Ag/ITO, but is not limited thereto. For example, embodiments are not limited thereto, and the first electrode AE may include the above-described metal materials, a combination of two or more metal materials selected from the above-described metal materials, or oxides of the above-described metal materials.

The pixel defining film PDL may be on the sixth insulating layer INS6. The pixel defining film PDL may be formed of a polymer resin. For example, the pixel defining film PDL may be formed including a polyacrylate-based resin or a polyimide-based resin. For example, the pixel defining film PDL may be formed by further including an inorganic material in addition to the polymer resin. The pixel defining film PDL may be formed including a light absorbing material, or may be formed including a black pigment or a black dye. The pixel defining film PDL including a black pigment or black dye may form a black pixel defining film. When forming the pixel defining film PDL, carbon black may be used as a black pigment or a black dye, but embodiments are not limited thereto.

For example, the pixel defining film PDL may be formed of an inorganic material. For example, the pixel defining film PDL may be formed of silicon nitride (SiNx), silicon oxide (SiOx), silicon oxynitride (SiOxNy), and/or the like.

A light emitting opening PX_OP exposing a portion of the first electrode AE may be defined in the pixel defining film PDL. A portion of the first electrode AE exposed by the light emitting opening PX_OP may be defined as a light emitting region LA.

The active region AA-DM of the display module DM may include the light emitting region LA and a light blocking region NLA. A region in which the pixel defining film PDL is arranged may correspond to the light blocking region NLA. The light blocking region NLA may surround the light emitting region LA in the active region AA-DM.

The hole control layer HCL may be on the first electrode AE and the pixel defining film PDL. The hole control layer HCL may be provided as a common layer that overlaps the light emitting region LA and the light blocking region NLA. The hole control layer HCL may include at least one of a hole transport layer, a hole injection layer, or an electron blocking layer. The hole control layer HCL may include hole injection materials and/or hole transport materials.

The emission layer EML may be on the hole control layer HCL. The emission layer EML may be in a region corresponding to the light emitting opening PX_OP. Alternatively, the emission layer EML may be provided as a common layer. The emission layer EML may include an organic light emitting material and/or an inorganic light emitting material. For example, the emission layer EML may emit color light of any one of red, green, and blue. For example, the emission layer EML may emit blue light.

The electron control layer TCL may be on the emission layer EML. The electron control layer TCL may be provided as a common layer that overlaps the light emitting region LA and the light blocking region NLA. The electron control layer TCL may include at least one of an electron transport layer, an electron injection layer, or a hole blocking layer. The electron control layer TCL may include known electron injection materials and/or known electron transport materials.

The second electrode CE may be on the electron control layer TCL. The second electrode CE may be provided as a common layer that overlaps the light emitting region LA and the light blocking region NLA.

The second electrode CE may be a common electrode. The second electrode CE may be a cathode or an anode. For example, when the first electrode AE is an anode, the second electrode CE may be a cathode, and when the first electrode AE is a cathode, the second electrode CE may be an anode.

The second electrode CE may be a transmissive electrode, a transflective electrode, or a reflective electrode. When the second electrode CE is a transmissive electrode, the second electrode CE may be formed of a transparent metal oxide, for example, indium tin oxide (ITO), indium zinc oxide (IZO), zinc oxide (ZnO), indium tin zinc oxide (ITZO), and/or the like.

When the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, or a compound/mixture thereof (e.g., AgMg, AgYb, or MgYb). Alternatively, the second electrode CE may have a multi-layer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the second electrode CE may include the above-described metal materials, a combination of two or more metal materials selected from the above-described metal materials, or oxides of the above-described metal materials.

The encapsulation layer TFE may be on the second electrode CE and may thus cover the light emitting element ED. The encapsulation layer TFE may include a plurality of thin films. For example, the encapsulation layer TFE may include inorganic layers on the second electrode CE and an organic layer between the inorganic layers. The inorganic film may protect the light emitting element ED from moisture/oxygen, and the organic film may protect the light emitting element ED from foreign substances, such as dust particles.

The input sensing portion TP may include a first sensing insulating layer IL1, a second sensing insulating layer IL2, and a third sensing insulating layer IL3. The input sensing portion TP may include at least one conductive layer on the sensing insulating layers. The input sensing portion TP may include a first conductive layer CDL1 and a second conductive layer CDL2.

The first sensing insulating layer IL1 may be on the encapsulation layer TFE. The first sensing insulating layer IL1 may include at least one inorganic insulating layer. The first sensing insulating layer IL1 may be in contact with the encapsulation layer TFE. Alternatively, the first sensing insulating layer IL1 may not be provided, and in this case, the first conductive layer CDL1 may contact the encapsulation layer TFE.

The first conductive layer CDL1 may be on the first sensing insulating layer IL1. The first conductive layer CDL1 may include a plurality of first conductive patterns. The plurality of first conductive patterns may be on the first sensing insulating layer IL1. The second sensing insulating layer IL2 may be on the first sensing insulating layer IL1 to cover at least a portion of the first conductive layer CDL1.

The second conductive layer CDL2 may be on the second sensing insulating layer IL2. The second conductive layer CDL2 may include a plurality of second conductive patterns. The plurality of second conductive patterns may be on the second sensing insulating layer IL2. The plurality of second conductive patterns may each be connected to the plurality of first conductive patterns through a contact hole formed in the second sensing insulating layer IL2.

The plurality of first conductive patterns of the first conductive layer CDL1 and the plurality of second conductive patterns of the second conductive layer CDL2 may each be arranged to correspond to the light blocking region NLA. The plurality of first conductive patterns of the first conductive layer CDL1 and the plurality of second conductive patterns of the second conductive layer CDL2 may each correspond to a mesh pattern.

The third sensing insulating layer IL3 may be on the second sensing insulating layer IL2 and may cover the second conductive layer CDL2. The second sensing insulating layer IL2 and the third sensing insulating layer IL3 may each include an inorganic insulating layer or an organic insulating layer.

The first conductive layer CDL1 and the second conductive layer CDL2 each may have a single-layered structure or may have a multi-layered structure stacked along the third direction DR3. The single-layered conductive layers CDL1 and CDL2 may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and indium zinc tin oxide (IZTO). For example, the transparent conductive layer may include a conductive polymer such as PEDOT, metal nanowire, graphene, and/or the like.

The multi-layered conductive layers CDL1 and CDL2 may include metal layers. For example, the metal layers may have a three-layer structure of titanium (Ti)/aluminum (Al)/titanium (Ti). The multi-layered conductive layers CDL1 and CDL2 may include at least one metal layer and at least one transparent conductive layer.

FIGS. 7A-7D are views schematically showing a method for preparing an adhesive member AP from a resin composition RC according to one or more embodiments. For example, the method for preparing an adhesive member AP may include providing a resin composition RC on a substrate CF, providing first light UV-1 to the resin composition RC to form a preliminary adhesive member P-AP, and providing second light UV-2 to the preliminary adhesive member P-AP to form an adhesive member AP. To provide descriptions with reference to FIGS. 7A-7D, descriptions that overlap the descriptions provided with reference to FIGS. 1-6 will not be provided, and differences will be mainly described.

Referring to FIG. 7A, the resin composition RC according to one or more embodiments may be provided onto the substrate CF. The resin composition RC may be provided onto the substrate CF through a nozzle NZ. For example, the substrate CF on which the resin composition RC is provided may include polyethylene terephthalate (PET). The substrate CF is a temporary substrate used to form the adhesive member AP (FIGS. 4 and 5) from the resin composition RC, and may be used without limitation as long as it is easily detached after the resin composition RC is cured. One surface of the substrate CF on which the resin composition RC is provided may be subjected to release treatment.

The resin composition RC according to one or more embodiments may be provided through an inkjet printing method or a dispensing method. In one or more embodiments, a liquid resin composition RC may be provided in a uniform amount and/or at a uniform rate. FIG. 7A shows that the resin composition RC is provided through the nozzle NZ, but the device for providing the resin composition RC is not limited thereto.

The resin composition RC may include a urethane (meth)acrylate oligomer, and a polymer including a unit derived from a cyclodextrin that does not have a (meth)acryloyl group.

In one or more embodiments, the (meth)acrylate indicates acrylate or methacrylate. For example, herein the (meth)acryloyl group indicates an acryloyl group or a methacryloyl group, and the (meth)acryl indicates acryl or methacryl.

A resin composition according to one or more embodiments includes a urethane (meth)acrylate oligomer, and a polymer including a unit derived from a cyclodextrin that does not have a (meth)acryloyl group together, and may thus exhibit excellent adhesive properties, durability, impact resistance, and flexibility. A resin composition including a urethane (meth)acrylate oligomer or a polymer including a unit derived from a cyclodextrin that does not have a (meth)acryloyl group hardly secures both excellent or suitable adhesive properties and impact resistance. For example, the resin composition according to one or more embodiments includes a unit derived from a cyclodextrin that does not have a (meth)acryloyl group, and may exhibit superior adhesive properties and more readily secure both excellent or suitable adhesive properties and impact resistance compared to when including a unit derived from a cyclodextrin having a (meth)acryloyl group.

In one or more embodiments, the polymer may include a cyclodextrin that does not have a (meth)acryloyl group or a derivative thereof. The polymer may be synthesized from a reactant including a cyclodextrin derivative that does not have a (meth)acryloyl group and a multifunctional isocyanate-based compound, but is not limited thereto. For example, the polymer may be a polyurethane in which a cyclodextrin derivative that does not have a (meth)acryloyl group is covalently bonded, but is not limited thereto.

For example, the cyclodextrin derivative that does not have a (meth)acryloyl group may include at least one selected from among hydroxypropyl cyclodextrin, hydroxyethyl cyclodextrin, methylated cyclodextrin, ethylated cyclodextrin, or benzylated cyclodextrin.

The multifunctional isocyanate-based compound may include at least one selected from among toluene diisocyanate, diphenylmethane diisocyanate, xylene diisocyanate, methylenediphenylmethane diisocyanate, isophorone diisocyanate (IPDI), cyclohexane diisocyanate, or hexamethylene diisocyanate.

The polymer may have a weight average molecular weight (Mw) of about 10,000 g/mol to about 100,000 g/mol. For example, the polymer may have a weight average molecular weight (Mw) of about 15,000 g/mol to about 100,000 g/mol, about 30,000 g/mol to about 100,000 g/mol, about 55,000 g/mol to about 90,000 g/mol, about 60,000 g/mol to about 85,000 g/mol, or about 65,000 g/mol to about 80,000 g/mol. The weight average molecular weight may be a value derived by standard polystyrene conversion using gel permeation chromatography.

The polymer may be provided in an amount of about 2 wt % to about 20 wt % with respect to a total weight of the resin composition. For example, the polymer may be provided in an amount of about 2 wt % to about 15 wt %, about 2.5 wt % to about 10 wt %, about 3 wt % to about 10 wt %, or about 3 wt % to about 8.5 wt %, with respect to a total weight of the resin composition. When the polymer remains within the above amount range, both excellent or suitable adhesive properties and impact resistance may be more readily secured.

In the resin composition RC according to one or more embodiments, the urethane (meth)acrylate oligomer may be a single type (kind), or may be used in combination with two or more types.

The urethane (meth)acrylate oligomer may have a weight average molecular weight (Mw) of about 5,000 g/mol to about 30,000 g/mol. For example, the urethane (meth)acrylate oligomer may have a weight average molecular weight (Mw) of about 6,000 g/mol to about 30,000 g/mol, about 10,000 g/mol to about 30,000 g/mol, about 12,000 g/mol to about 28,000 g/mol, about 13,000 g/mol to about 25,000 g/mol, or about 13,000 g/mol to about 23,000 g/mol.

The urethane (meth)acrylate oligomer may be provided in an amount of about 2 wt % to about 20 wt % with respect to a total weight of the resin composition. For example, the urethane (meth)acrylate oligomer may be provided in an amount of about 2 wt % to about 16 wt %, about 2.5 wt % to about 12 wt %, about 2.5 wt % to about 10 wt %, about 3 wt % to about 10 wt %, or about 3 wt % to about 8.5 wt %, with respect to a total weight of the resin composition.

For example, a weight ratio of the urethane (meth)acrylate oligomer and the polymer may be about 1:0.2 to about 1:2.5. For example, the urethane (meth)acrylate oligomer and the polymer may be present at a weight ratio of about 1:0.3 to about 1:2.5, about 1:0.3 to about 1:2.3, or about 1:0.35 to about 1:2.1. When the urethane (meth)acrylate oligomer and the polymer remain within the above weight ratio range, both excellent or suitable adhesive properties and impact resistance may be more easily secured.

The resin composition may further include a monofunctional (meth)acrylate monomer. For example, the monofunctional (meth)acrylate monomer may include at least one of 4-hydroxybutyl acrylate, 2-methoxyethyl acrylate, 2-hydroxyethyl acrylate, 2-hydroxypropyl acrylate, 2-hydroxybutyl acrylate, tetrahydrofurfuryl acrylate, isobornyl acrylate, 2-ethylhexyl acrylate, n-butyl acrylate, t-butyl acrylate, isodecyl acrylate, lauryl acrylate, stearyl acrylate, or isostearyl acrylate. However, the monofunctional (meth)acrylate monomer is not limited to the types described above, and may be used without limitation as long as it is within the range that may be appropriately selected by those skilled in the art.

The monofunctional (meth)acrylate monomer may be provided in an amount of about 60 wt % to about 95 wt % with respect to a total weight of the resin composition. For example, the monofunctional (meth)acrylate monomer may be provided in an amount of about 65 wt % to about 95 wt %, about 70 wt % to about 95 wt %, about 75 wt % to about 95 wt %, about 80 wt % to about 93 wt %, or about 82 wt % to about 93 wt %, or about 84 wt % to about 92 wt %, with respect to a total weight of the resin composition.

For example, the resin composition RC may further include a photopolymerization initiator. The photopolymerization initiator may indicate a material that may absorb light, such as UV light, and subsequently cause polymerization reaction of monomers or oligomers.

For example, the photopolymerization initiator may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

For example, the photopolymerization initiator may further include at least one of 2-methyl-1[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, bis(2,4,6-trimethylbenzoyl)phenyl phosphine oxide, [1-(4-phenylsulfanylbenzoyl)heptylideneamino]benzoate, [1-[9-ethyl-6-(2-methylbenzoyl)carbazol-3-yl]ethylideneamino]acetate, or bis(2,4-cyclopentadienyl)bis [2,6-difluoro-3-(1-pyrryl)phenyl] titanium (IV).

In one or more embodiments, the resin composition may include at least one of bis(2,4,6-trimethylbenzoyl)phenyl phosphine oxide or α-hydroxy alkyl phenone, as the photopolymerization initiator. The photopolymerization initiator may be a single type (kind), or may be used in combination with two or more types. However, the photopolymerization initiator is not limited to the types described above, and may be used without limitation as long as it is within the range that may be appropriately selected by those skilled in the art.

The resin composition RC according to one or more embodiments may have a glass transition temperature (Tg) of about −30° C. to about 20° C. after being irradiated with UV light until the accumulated light dose reaches about 5,000 mJ/cm² in the atmosphere. For example, the adhesive member AP including a polymer derived from the resin composition RC according to one or more embodiments may have a glass transition temperature (Tg) of about −30° C. to about 10° C., about −30° C. to about 5° C., or about −30° C. to about 0° C.

The resin composition RC according to one or more embodiments may have a 180° peel strength of about 600 gf/25 mm or greater on a glass substrate measured at about 25° C. after being irradiated with UV light until the accumulated light dose reaches about 5,000 mJ/cm² in the atmosphere. For example, the adhesive member AP including a polymer derived from the resin composition RC according to one or more embodiments may have a 180° peel strength of about 650 gf/25 mm or greater, about 750 gf/25 mm or greater, or about 800 gf/25 mm or greater on a glass substrate measured at about 25° C.

The resin composition RC according to one or more embodiments may have a 180° peel strength of about 150 gf/25 mm or greater on a glass substrate measured at about 60° C. after being irradiated with UV light until the accumulated light dose reaches about 5,000 mJ/cm² in the atmosphere. For example, the adhesive member AP including a polymer derived from the resin composition RC according to one or more embodiments may have a 180° peel strength of about 160 gf/25 mm or greater, about 180 gf/25 mm or greater, or about 200 gf/25 mm or greater on a glass substrate measured at about 60° C.

The resin composition RC according to one or more embodiments may have a storage elastic modulus of about 0.8 Mpa to about 2.5 Mpa at about −25° C. after being irradiated with UV light until the accumulated light dose reaches about 5,000 mJ/cm² in the atmosphere. For example, the adhesive member AP including a polymer derived from the resin composition RC according to one or more embodiments may have a storage modulus of about 0.9 Mpa or greater, about 1.0 Mpa or greater, or about 1.1 Mpa or greater at about −25° C., and may be about 2.2 Mpa or less, about 2.0 Mpa or less, or about 1.5 Mpa or less at about −25° C. Referring to FIG. 7B, first light UV-1 may be provided to the resin composition RC applied at a constant thickness on a substrate CF. A liquid resin composition RC may be cured by the first light UV-1 to form a preliminary adhesive member P-AP (FIG. 7C). The first light UV-1 may be UV light. FIG. 7B shows that the resin composition RC applied on the substrate CF is directly irradiated with the first light UV-1 to form the preliminary adhesive member P-AP, but embodiments are not limited thereto. A carrier film (not shown) may be on the resin composition RC applied to a uniform thickness, and the carrier film may transmit UV light.

Referring to FIGS. 7C and 7D, the preliminary adhesive member P-AP formed by irradiating the resin composition RC with the first light UV-1 (FIG. 7B) may be detached from the substrate CF and provided on one surface of the window WP or on one surface of the display module DM. One surface of the preliminary adhesive member P-AP may be laminated on one surface of the window WP or one surface of the display module DM, and one surface of the display module DM or one surface of the window WP that is not attached may be attached to the other surface of the preliminary adhesive member P-AP. Thereafter, the preliminary adhesive member P-AP may be irradiated with second light UV-2 to form the adhesive member AP (FIGS. 4 and 5). The second light UV-2 may be UV light. The second light UV-2 may be provided from an upper portion of the window WP, and the window WP may transmit the second light UV-2. The second light UV-2 may be transmitted through the window WP and provided to the preliminary adhesive member P-AP. For example, the second light UV-2 may be transmitted through the printing layer BM and provided to the preliminary adhesive member P-AP.

An area of the preliminary adhesive member P-AP that overlaps the printing layer BM may be irradiated with a smaller amount of second light UV-2, rather than another area of the preliminary adhesive member P-AP that does not overlap the printing layer BM.

FIGS. 7A-7D show that the adhesive member AP (FIGS. 4 and 5) is formed by curing the resin composition RC twice (i.e., curing by providing light twice), but embodiments are not limited thereto. For example, the adhesive member AP may be formed by curing the resin composition RC once, or the adhesive member AP may be formed by curing the resin composition RC three or more times.

FIGS. 8A-8C are views schematically showing another method for preparing an adhesive member AP from a resin composition RC according to one or more embodiments. To provide descriptions with reference to FIGS. 8A-8C, descriptions that overlap the descriptions provided with reference to FIGS. 1-7D will not be provided, and differences will be mainly described.

The method for preparing an adhesive member AP shown in FIGS. 8A-8C may include providing a resin composition RC on a display module DM, providing first light UV-1 to the resin composition RC to form a preliminary adhesive member P-AP, and providing second light UV-2 to the preliminary adhesive member P-AP to form an adhesive member AP. The preparation method shown in FIGS. 8A-8C differs from the preparation method shown in FIGS. 7A-7D in that the resin composition RC is provided on the display module DM.

The resin composition RC may be directly provided on one side of the display module DM or one side of the window WP. FIG. 8A shows that the resin composition RC is directly provided on one surface of the display module DM.

Referring to FIG. 8B, the first light UV-1 may be provided to the uniformly applied resin composition RC. As the first light UV-1 is provided to the resin composition RC, the preliminary adhesive member P-AP may be formed. The window WP may be provided on the preliminary adhesive member P-AP. Referring to FIG. 8C, the second light UV-2 may pass through the window WP and be provided to the preliminary adhesive member P-AP. For example, the second light UV-2 may be transmitted through the printing layer BM and provided to the preliminary adhesive member P-AP. The preliminary adhesive member P-AP may be cured through the second light UV-2 to form the adhesive member AP (FIG. 5).

The adhesive member AP (FIG. 5) formed from the resin composition RC according to one or more embodiments may exhibit high adhesive strength and excellent or suitable light resistance. For example, the adhesive member AP (FIG. 5) formed from the resin composition RC according to one or more embodiments may exhibit high adhesive strength and excellent light resistance even under the printing layer BM.

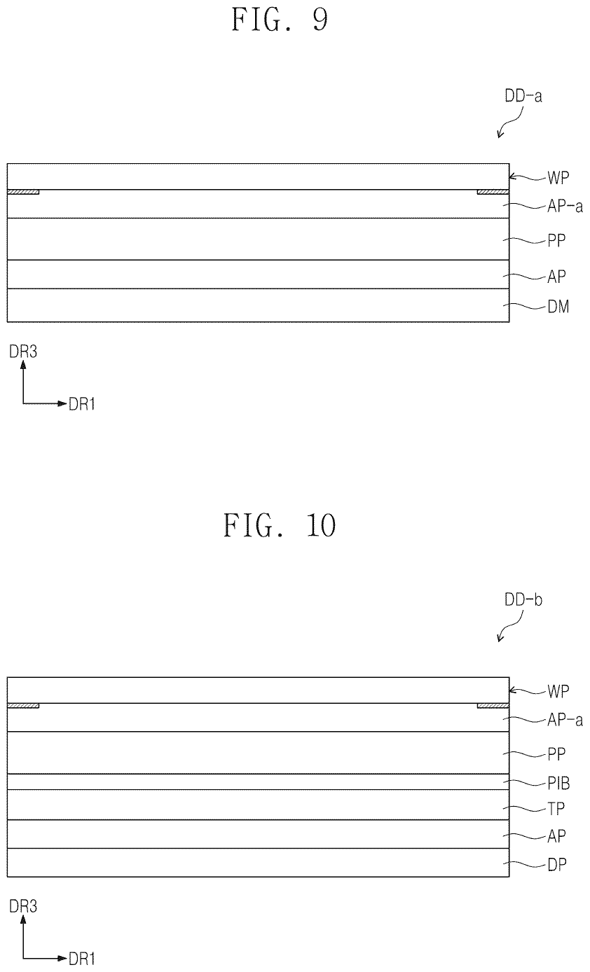

FIGS. 9 and 10 are each cross-sectional views showing a display device according to one or more embodiments. Hereinafter, in the description of the display device according to one or more embodiments with reference to FIGS. 9 and 10, content that overlaps the one described above with reference to FIGS. 1-8C will not be described again, and the differences will be mainly described.

Compared with the display device DD described with reference to FIGS. 4 and 5, a display device DD-a shown in FIG. 9 may further include a light control layer PP and an optical adhesive layer AP-a. The display device DD-a according to one or more embodiments may further include a light control layer PP between the adhesive member AP and the window WP, and an optical adhesive layer AP-a between the light control layer PP and the window WP. The light control layer PP may include a polarizing plate or a color filter layer.

The optical adhesive layer AP-a may be formed from the resin composition RC according to one or more embodiments. The optical adhesive layer AP-a including a polymer derived from the resin composition RC may exhibit excellent or suitable adhesive strength and excellent or suitable light resistance. The display device DD including the optical adhesive layer AP-a may exhibit excellent or suitable reliability and excellent or suitable display quality.

Compared with the display device DD described with reference to FIGS. 4 and 5, a display device DD-b according to one or more embodiments shown in FIG. 10 may further include a light control layer PP, an optical adhesive layer AP-a, and an interlayer adhesive layer PIB.

In the display device DD-b according to one or more embodiments, the adhesive member AP may be provided between the display panel DP and the input sensing portion TP. For example, the input sensing portion TP may not be directly on the display panel DP, and the display panel DP and the input sensing portion TP may be bonded through the adhesive member AP. For example, the adhesive member AP may be between the encapsulation layer TFE (FIG. 5) of the display panel DP and the input sensing portion TP.

The interlayer adhesive layer PIB may be provided below the light control layer PP. The interlayer adhesive layer PIB may be between the input sensing portion TP and the light control layer PP and may be formed of an adhesive material having excellent or suitable moisture permeation prevention properties. For example, the interlayer adhesive layer PIB may be formed including polyisobutylene. The interlayer adhesive layer PIB may be on the input sensing portion TP to prevent corrosion of sensing electrodes of the input sensing portion TP. The display device DD-b according to one or more embodiments includes the optical adhesive layer AP-a and the adhesive member AP formed from the resin composition RC according to one or more embodiments, and the display device DD-b including the optical adhesive layer AP-a and the adhesive member AP may exhibit excellent or suitable reliability and exhibit excellent or suitable display quality.

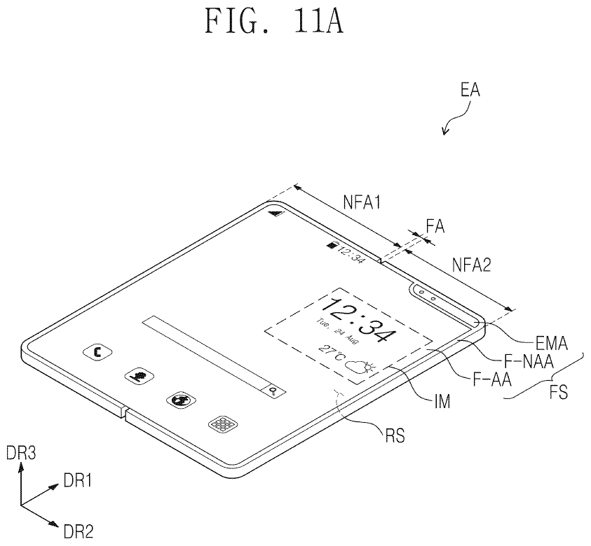

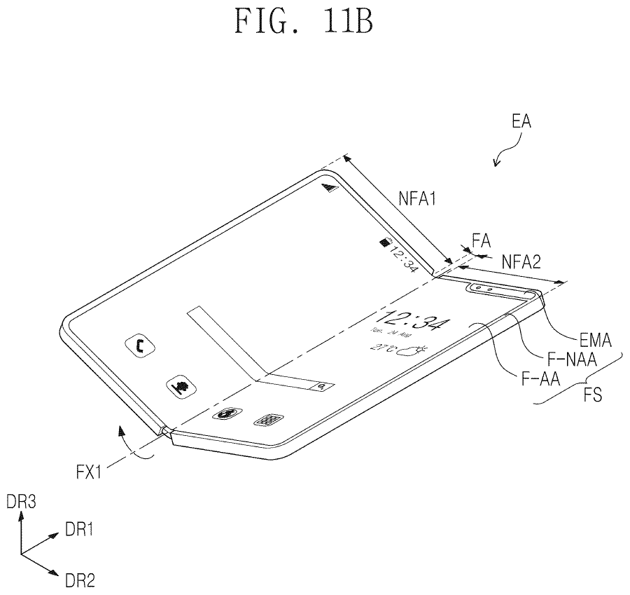

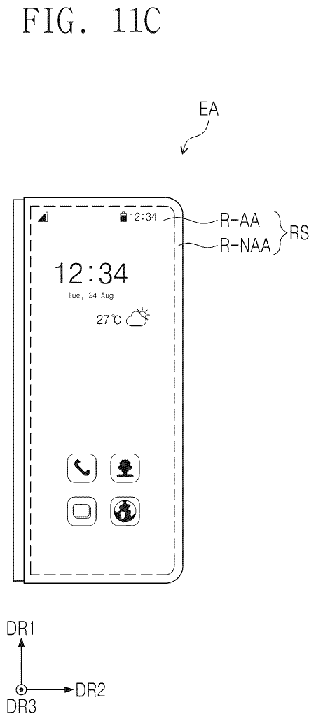

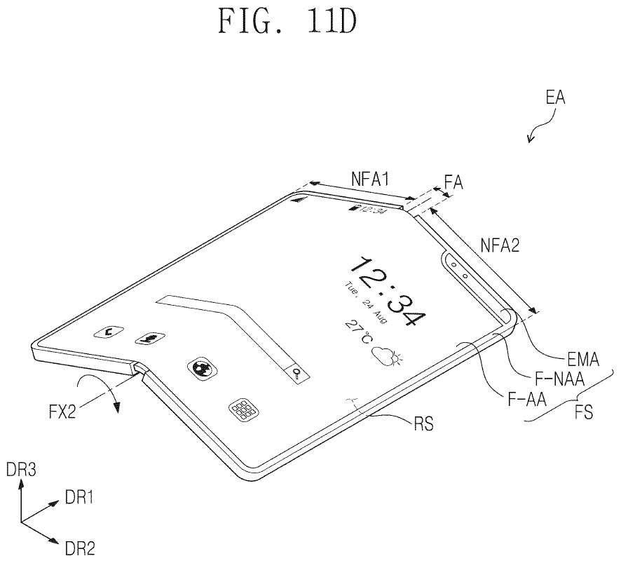

The electronic device EA according to one or more embodiments may be flexible as described above. FIGS. 11A-11D are each a perspective view or a plan view showing the electronic device according to one or more embodiments described above. Hereinafter, in the description of the electronic device according to one or more embodiments with reference to FIGS. 11A-11D, content that overlaps the one described above with reference to FIGS. 1-10 will not be described again, and the differences will be mainly described.

FIG. 11A is a perspective view showing a state in which the electronic device EA according to one or more embodiments is unfolded. The electronic device EA according to one or more embodiments may be a device activated in response to electrical signals. For example, the electronic device EA may be a mobile phone, a tablet, a car navigation system, a game console, or a wearable device, but embodiments are not limited thereto. In FIG. 11A, a mobile phone is shown as an example of the electronic device EA.

In one or more embodiments, the first directional axis DR1 and the second directional axis DR2 may be perpendicular to each other, and the third directional axis DR3 may be a normal direction to a plane defined by the first direction axis DR1 and the second directional axis DR2. A thickness direction of the electronic device EA may be parallel to the third directional axis DR3. A front surface (or upper surface) and a rear surface (or lower surface) may oppose each other, and a normal direction of each of the front surface (or upper surface) and the rear surface (or lower surface) may be parallel to the third directional axis DR3. The front surface (or upper surface) indicates a surface adjacent to the first display surface FS, and the rear surface (or lower surface) indicates a surface spaced apart from the first display surface FS. For example, the rear surface (or lower surface) indicates a surface close to a second display surface RS, which will be described in more detail in the text. The upper surface indicates a direction towards the first display surface FS, and the lower surface indicates a direction away from the first display surface FS.

Cross-sections indicate a surface parallel to the thickness direction DR3, and planes indicate a surface perpendicular to the thickness direction DR3. The planes indicate a plane defined by the first directional axis DR1 and the second directional axis DR2.

Directions indicated by the first to third directional axes DR1, DR2, and DR3 as described herein are relative concepts, and may thus be changed to other directions. For example, the directions indicated by the first to third directional axes DR1, DR2, and DR3 may be described as first to third directions, and the same reference signs may be used.

The electronic device EA may sense external inputs applied from the outside. The external inputs may include various suitable forms of inputs provided from the outside the electronic device EA. For example, the external inputs may include external inputs applied when approaching the electronic device EA or being adjacent by a certain distance (e.g., hovering), as well as through contact by a part of a body such as a user's hand. For example, the external inputs may have various forms such as force, pressure, temperature, light, and/or the like.

The electronic device EA may include the first display surface FS and the second display surface RS. The first display surface FS may include a first active region F-AA, a first peripheral region F-NAA, and an electronic module region EMA. The second display surface RS may be defined as a surface opposing at least a portion of the first display surface FS. For example, the second display surface RS may be defined as a portion of the rear surface of the electronic device EA.

The first active region F-AA may be a region activated according to electrical signals. The first active region F-AA may be a region displaying the image IM and sensing various forms of external inputs.

The first peripheral region F-NAA may be adjacent to the first active region F-AA. The first peripheral region F-NAA may have several colors. The first peripheral region F-NAA may surround the first active region F-AA. Accordingly, the shape of the first active region F-AA may be substantially defined by the first peripheral region F-NAA. However, this is presented as an example, and the first peripheral region F-NAA may be adjacent to only one side of the first active region F-AA, or may not be provided.

The electronic module region EMA may include one or more suitable electronic modules. For example, the electronic module may include at least any one selected from among a camera, a speaker, a light detection sensor, or a heat detection sensor. The electronic module region EMA may sense an external subject received through the display surfaces FS and RS, or provide sound signals such as voice to the outside through the display surfaces FS and RS. The electronic modules may include a plurality of components, and are not limited to the embodiments.

The electronic module region EMA may be surrounded by the first peripheral region F-NAA. However, this is merely an example, and the above-mentioned configuration is not limited to the embodiments. For example, the electronic module region EMA may be surrounded by the first active region F-AA and the first peripheral region F-NAA, and the electronic module region EMA may be in the first active region F-AA.

The electronic device EA according to one or more embodiments may be a flexible electronic device. The electronic device EA according to one or more embodiments may include at least one folding region FA and a plurality of non-folding regions NFA1 and NFA2 extending from the folding region FA. For example, the first non-folding region NFA1, the folding region FA, and the second non-folding region NFA2 may be defined in the second direction DR2. The electronic device EA according to one or more embodiments may include the first non-folding region NFA1 and the second non-folding region NFA2, which are spaced apart with the folding region FA1 therebetween in the first direction DR2. For example, the first non-folding region NFA1 may be at one side of the folding region FA in the second direction DR2, and the second non-folding region NFA2 may be at the other side of the folding region FA in the second direction DR2.

FIG. 11A shows one or more embodiments of the electronic device EA including one folding region FA, but embodiments are not limited thereto, and in the electronic device EA, a plurality of folding regions may be defined. For example, the electronic device according to one or more embodiments may include two or more folding regions and three or more non-folding regions with each of the folding regions therebetween.

FIG. 11B is a perspective view showing a folding operation of the electronic device EA according to one or more embodiments. FIG. 11C is a plan view showing a state in which the electronic device EA according to one or more embodiments is folded. FIG. 11D is a perspective view showing a folding operation of the electronic device EA according to one or more embodiments.

Referring to FIG. 11B, the electronic device EA according to one or more embodiments may be folded with respect to a first folding axis FX1 extending in the first direction DR1. When the electronic device EA is folded, the folding region FA may have a slight curvature and radius of curvature. For example, the folding region FA may have radius of curvature of about 5 mm or less. The electronic device EA may be folded with respect to the first folding axis FX1 to become in-folded such that the first non-folding region NFA1 and the second non-folding region NFA2 face each other and the first display surface FS is not exposed to the outside.

Referring to FIG. 11C, in the state where the electronic device EA according to one or more embodiments is in-folded, the second display surface RS may be viewed by users. In one or more embodiments, the second display surface RS may include a second active region R-AA displaying images. The second active region R-AA may be a region activated according to electrical signals. The second active region R-AA may be a region displaying images and sensing various forms of external inputs.

A second peripheral region R-NAA may surround the second active region R-AA. The second peripheral region R-NAA may have several colors. The second peripheral region R-NAA may surround the second active region R-AA. For example, although not shown, the electronic device EA may further include an electronic module region, in which an electronic module including various suitable components is arranged, in the second display surface RS, and is not limited to the embodiments.

Referring to FIG. 11D, the electronic device EA according to one or more embodiments may be folded with respect to a second folding axis FX2 extending in the first direction DR1. When the electronic device EA is folded, the folding region FA may have a slight curvature and radius of curvature. For example, the folding region FA may have radius of curvature of about 5 mm or less. The electronic device EA may be folded with respect to the second folding axis FX2 to become out-folded such that the first display surface FS is exposed to the outside. In one or more embodiments, the electronic device EA may be configured such that the in-folding operation or the out-folding operation is mutually repeated from the unfolding operation, but is not limited thereto.

FIGS. 11A-11D show that the electronic device EA is folded with respect to one folding axis AX1 or AX2 as examples, but the number of folding axes and the corresponding number of non-folding regions are not limited thereto. For example, the electronic device EA may be folded with respect to a plurality of folding axes such that a portion of the first display surface FS faces a portion of the second display surface RS. For example, it is shown that the first and second folding axes FX1 and FX2 are directed parallel to a long side of the electronic device EA, but embodiments are not limited thereto, and the first and second folding axes FX1 and FX2 may be directed parallel to a short side of the electronic device EA.

In one or more embodiments, when the electronic device EA is in the folded state as shown in FIG. 11C, the first non-folding region NFA1 and the second non-folding region NFA2 may be defined as portions having display surfaces FS and RS directed parallel to a plane defined by the first directional axis DR1 and the second directional axis DR2, and the folding region FA may be defined as a region between the first non-folding region NFA1 and the second non-folding region NFA2. The folding region FA may include a curved surface portion which is bent to have a slight curvature in the folded state. For example, the folding region FA may have radius of curvature of about 5 mm or less.

Hereinafter, with reference to Examples and Comparative Examples, the resin composition according to one or more embodiments of the present disclosure and the adhesive member formed from the resin composition will be specifically described. For example, Examples below are shown only for the understanding of the present disclosure, and the scope of the present disclosure is not limited thereto.

### EXAMPLES

### 1. Preparation of Resin Composition

(1) Preparation of urethane (meth)acrylate Oligomer (UA-1)

A four-necked flask equipped with a cooling tube, a dry air inlet tube, a temperature sensor, and a stirrer was used as a reaction vessel. 100 g of PTMG 2000 (polytetramethylene ether glycol), 4.2 g of hexamethylene diisocyanate (manufactured by Tokyo Chemical Industry Co., Ltd.), 0.011 g of MEHQ (4-methoxyphenol, manufactured by Tokyo Chemical Industry Co., Ltd.), and 0.056 g of DBTDL (dibutyltin dilaurate) were added to the reaction vessel and subjected to reaction at 70° C. for 2 hours or more. In one or more embodiments, reaction solution samples were taken every 30 minutes starting from 2 hours and an IR spectrum was measured. After about 3 hours, it was confirmed that there was no peak change attributable to NCO, and then 4.7 g of 2-HEA (2-hydroxyethyl acrylate) was additionally introduced. After about an hour, a reaction solution sample was taken and an IR spectrum was measured. Upon confirming the disappearance of NCO, the solution was cooled to room temperature to obtain a urethane (meth)acrylate oligomer (UA-1) having a weight average molecular weight (Mw) of 17,000 g/mol.

In one or more embodiments, the weight average molecular weight was measured using a gel permeation chromatography (GPC) analyzer (trade name: HLC-8420GPC, manufactured by TOSOH). Values obtained by standard polystyrene (PS) conversion from the SEC curve detected by an RI detector using a TSKgel SuperHZM-N measurement column and THF measurement solvent were adopted as the weight average molecular weight.

### (2) Preparation of Polymer (CD-1)

A four-necked flask equipped with a cooling tube, a dry air inlet tube, a temperature sensor, and a stirrer was used as a reaction vessel. 34 g of PTMG 2000, 2.16 g of YNB-W97 (β-cyclodextrin diol, manufactured by Yushiro Chemical), 0.008 g of MEHQ, 0.082 g of BHT (2,6-di-tert-butyl-p-cresol, manufactured by Tokyo Chemical Industry Co., Ltd.), 0.002 g of DBTDL, and 41 g of THF-A (tetrahydrofurfuryl acrylate, manufactured by Kyoeisha Chemical Co., Ltd.) were added to a reaction vessel and mixed at 70° C. After confirming that a homogeneous solution was formed, 11.6 g of hexamethylene diisocyanate (manufactured by Tokyo Chemical Industry Co., Ltd.) was added and stirred at 80° C. for reaction. In this case, reaction solution samples were taken every 30 minutes starting from 2 hours and an IR spectrum was measured. After about 4 hours, it was confirmed that there was no peak change attributable to NCO, and then 0.7 g of ethanol was additionally introduced. After about an hour, a reaction solution sample was taken and an IR spectrum was measured. Upon confirming the disappearance of NCO, the solution was cooled to room temperature to obtain a polyurethane (CD-1) containing a unit derived from a cyclodextrin that does not have a (meth)acryloyl group, with a weight average molecular weight (Mw) of 72,000 g/mol.

### (3) Preparation of Resin Composition

Tables 1 to 3 show the compositional components and contents for the resin compositions of Examples and the resin compositions of Comparative Examples. Each component was added in a light-shielding, sealed container according to the mixing ratios listed in Tables 1 to 3 and the mixture was stirred at room temperature for 12 hours using a mixing roller to prepare the resin compositions of Examples and the resin compositions of Comparative Examples. The values listed in Tables 1 to 3 indicate parts by weight.

TABLE 1

| | | Example | Example | Example | Example |
|---|---|---|---|---|---|
| Components | | 1 | 2 | 3 | 4 |
| Monofunctional | A-1 | 10 | 10 | 10 | 10 |
| (meth)acrylate | A-2 | 50 | 50 | 50 | 50 |
| monomer | A-3 | 20 | 20 | 20 | 20 |
| | A-4 | 20 | 20 | 20 | 20 |
| Urethane (meth) | UA-1 | 8.3 | 6.3 | 4.2 | — |
| acrylate | UA-2 | — | — | — | 6.3 |
| Oligomer | | | | | |
| Polymer | CD-1 | 4.2 | 6.3 | 8.3 | 8.3 |
| Acrylate | ACCD | — | — | — | — |
| monomer | | | | | |
| containing | | | | | |
| cyclodextrin | | | | | |
| having | | | | | |
| (meth)acryloyl | | | | | |
| group | | | | | |
| Bifunctional | N-1 | — | — | — | — |
| (meth)acrylate | | | | | |
| monomer | | | | | |
| Photopoly- | Omni.819 | 2.0 | 2.0 | 2.0 | 2.0 |
| merization | | | | | |
| initiator | | | | | |

TABLE 2

| | | Comparative | Comparative | Comparative | Comparative |
|---|---|---|---|---|---|
| | | Example | Example | Example | Example |
| Components | | 1 | 2 | 3 | 4 |
| Monofunctional | A-1 | 10 | 10 | 10 | 10 |
| (meth)acrylate | A-2 | 50 | 50 | 50 | 50 |
| monomer | A-3 | 20 | 20 | 20 | 20 |
| | A-4 | 20 | 20 | 20 | 20 |
| Urethane (meth) | UA-1 | 12.5 | — | 12.5 | 12.5 |
| acrylate | UA-2 | — | 12.5 | — | — |
| Oligomer | | | | | |
| Polymer | CD-1 | — | — | — | — |
| Acrylate monomer | ACCD | — | — | — | 3.0 |
| containing | | | | | |
| cyclodextrin | | | | | |
| having | | | | | |
| (meth)acryloyl | | | | | |
| group | | | | | |
| Bifunctional | N-1 | — | — | 0.5 | — |
| (meth)acrylate | | | | | |
| monomer | | | | | |
| Photopolymerization | Omni.819 | 2.0 | 2.0 | 2.0 | 2.0 |
| initiator | | | | | |

### Data on Materials in Tables 1 and 2

A-1:4-HBA (4-hydroxybutyl acrylate, manufactured by Osaka Organic Chemical Industry Ltd.)
A-2:2-Methoxyethyl acrylate (manufactured by Tokyo Chemical Industry Co., Ltd.)
A-3: THF-A (tetrahydrofurfuryl acrylate, manufactured by Kyoeisha Chemical Co., Ltd.)
A-4:2-EHA (2-ethylhexyl acrylate, manufactured by Toagosei Co., Ltd.) UA-1: Urethane (meth)acrylate oligomer manufactured in (1)
UA-2: UN-6304 (manufactured by Negami Kogyo Co., Ltd.)
CD-1: Oligomer containing cyclodextrin that does not have a (meth)acryloyl group manufactured in Manufacturing Example (2)
ACCD: 2,3,6-tri-o-acetyl-mono-6-deoxy-6-acrylamido-β-cyclodextrin (manufactured by Yushiro Chemical)
N-1: Nonanediol diacrylate
Omni.819: Bis(2,4,6-trimethylbenzoyl)phenyl phosphine oxide (manufactured by IGM Resin)

### 2. Evaluation of Adhesive Member Characteristics

Tables 3 and 4 show the glass transition temperature, storage modulus, loss tangent, and peel strength of adhesive members formed from the resin compositions of Examples and Comparative Examples.

### (1) Glass Transition Temperature, Storage Modulus, and Loss Tangent

The glass transition temperature and storage modulus were measured using specimens obtained by curing each of the resin compositions of Examples and Comparative Examples.

A release-treated PET film (trade name: NP1000A, manufactured by Panac Co., Ltd.) and a silicone rubber sheet with an 8 mm diameter hole (manufactured by Tigers Polymer Co., Ltd.) were sequentially stacked on a slide glass (trade name and manufacturer: Matsunami Glass Slide Glass S1112). 28 μL of the resin composition was dropped into the hole portion of the silicone rubber sheet. The dropped resin composition was irradiated with UV light using a UV-LED lamp having peaks at 365 nm and 395 nm such that the provided light doses reached 600 mJ/cm² and 500 mJ/cm², respectively. A release-treated PET film (product name: NP1000A, manufactured by Panac Co., Ltd.) and a slide glass (Matsunami Glass Slide Glass S1112) were sequentially stacked on the UV-irradiated resin composition. After UV irradiation, the resin composition was cured through irradiation with UV light from the stacked slide glass side, using a UV-LED lamp having a peak at 395 nm, such that the provided light dose reached 5,000 mJ/cm². Accordingly, measurement specimens with an 8 mm diameter and a 500 μm thickness were obtained.

The glass transition temperature (Tg) after curing, the storage modulus at −25° C. and 25° C., and the loss tangent (tan δ) at 25° C. of the resin composition, which was a measurement specimen prepared using a dynamic viscoelasticity measurement device (trade name: MCR302, manufactured by Anton Paar), were measured. The glass transition temperature (Tg) and the storage modulus were measured at a frequency of 1 Hz, in shear mode, and at a heating rate of 2° C./min from −70° C. to 80° C. The glass transition temperature is recorded as the temperature at the peak of the loss tangent (tan δ) value.

### (2) Peel Strength

The Peel strength was measured using specimens obtained by curing each of the resin compositions of Examples and Comparative Examples.

The resin composition was applied onto a 26 mm×76 mm soda-lime glass (manufactured by Central Glass) using a bar coater to a thickness of 50 μm. The soda-lime glass where the resin composition was applied was irradiated with UV light using a UV-LED lamp having peaks at a wavelength of 365 nm and 395 nm, such that the respective accumulated light doses reached 600 mJ/cm² and 500 mJ/cm². A 20 mm×150 mm PET film (trade name: A4360, manufactured by Toyobo Co., Ltd.) was bonded onto the resin composition at a bonding pressure of 0.15 MPa. After bonding, the PET film was irradiated with UV light using a UV-LED lamp having a peak at a wavelength of 395 nm such that the accumulated light dose reached 5,000 mJ/cm² to obtain a specimen.

The peel strength of the specimen was measured using a universal testing machine (trade name: Instron 5965) at 25° C. or 60° C., a peel angle of 180°, and a peel speed of 300 mm/min. The peel strength was measured three times. After calculating the average value for about 50 mm of peeling, the peel strength was determined by conversion with a factor of 1.25. In this case, measurement at 60° C. was taken after keeping the specimen in a high-temperature test bath for 15 minutes.

### (3) Shock Absorption

A 500 μm thick silicone rubber sheet (manufactured by Tigers Polymer Co., Ltd.) with an 8 mm diameter hole was sequentially stacked on a release-treated PET film (trade name: NP1000A, manufactured by Panac Co., Ltd.). 240 μL of the resin composition was dropped into the hole portion of the silicone rubber sheet. The dropped resin composition was irradiated with UV light using a UV-LED lamp having peaks at a wavelength of 365 nm and 395 nm such that the provided light doses reached 600 mJ/cm² and 500 mJ/cm², respectively. The same PET film as described above and a 1 mm thick glass substrate were sequentially stacked on the irradiated resin composition. The resin composition was cured by irradiating ultraviolet rays to the glass substrate using a UV-LED lamp with a peak wavelength of 395 nm at an accumulated light dose of 5,000 mJ/cm², thereby obtaining a cured product having a thickness of 500 μm. A tensile test was performed on the cured product at a tensile speed of 0.83 mm/s at 25° C., and an area under the stress-strain curve up to the point of fracture was calculated as fracture energy. A larger fracture energy indicates higher shock absorption.

TABLE 3

| Evaluation | Example 1 | Example 2 | Example 3 | Example 4 |
|---|---|---|---|---|
| Glass transition | −26.0 | −30.0 | −27.0 | −30.0 |
| temperature (°C) | | | | |
| Storage modulus | 1.50 | 1.83 | 1.77 | 1.18 |
| (−25 °C, Mpa) | | | | |
| Storage modulus | 0.05 | 0.06 | 0.05 | 0.05 |
| (25 °C, Mpa) | | | | |
| Loss tangent | 0.42 | 0.46 | 0.49 | 0.42 |
| Peel strength (25 °C, | 840 | 1,420 | 1,100 | 1,470 |
| gf/25 mm) | | | | |
| Peel strength (60 °C, | 270 | 490 | 230 | 390 |
| gf/25 mm) | | | | |
| Fracture energy (kJ/m³) | 110 | 190 | 250 | 140 |

TABLE 4

| | | | | Com- |
|---|---|---|---|---|
| | Comparative | Comparative | Comparative | parative |
| Evaluation | Example 1 | Example 2 | Example 3 | Example 4 |
| Glass transition | −30.0 | −30.0 | −29.0 | −24 |
| temperature (°C) | | | | |
| Storage modulus | 0.29 | 0.20 | 0.42 | 3.15 |
| (−25 °C, Mpa) | | | | |
| Storage modulus | 0.05 | 0.05 | 0.06 | 0.09 |
| (25 °C, Mpa) | | | | |
| Loss tangent | 0.15 | 0.12 | 0.09 | 0.10 |
| Peel strength | 390 | 520 | 200 | 450 |
| (25 °C, gf/ | | | | |
| 25 mm) | | | | |
| Peel strength | 60 | 80 | 60 | 80 |
| (60 °C, gf/ | | | | |
| 25 mm) | | | | |
| Fracture energy | 100 | 50 | 20 | 100 |
| (kJ/m³) | | | | |

Referring to Tables 3 and 4, the adhesive members formed after photo-curing the resin compositions of Examples 1 to 4 had a 180° peel strength of 600 gf/25 mm or greater measured at 25° C. and a 180° peel strength of 150 gf/25 mm or greater measured at 60° C. Accordingly, it is seen that the adhesive members formed from the resin compositions according to one or more embodiments exhibit excellent or suitable adhesive reliability at room temperature and high temperature. For example, it is seen that the adhesive members obtained after photo-curing the resin compositions of Examples 1 to 4 had a glass transition temperature of −35° C. to 20° C., and had a calculated fracture energy of greater than 100 kJ/m³, thereby exhibiting appropriate durability and impact resistance. For example, it is seen that the adhesive members obtained after photo-curing the resin compositions of Examples 1 to 4 satisfy the desired range for storage modulus and loss tangent at −25° C. and 25° C., thereby securing appropriate flexibility and adhesive strength.

Conversely, the adhesive members obtained after photo-curing the resin compositions of Comparative Examples 1 to 4 had a 180° peel strength of 520 gf/25 mm or less measured at 25° C., and a 180° peel strength of 80 gf/25 mm or less measured at 60° C. Accordingly, it is seen that the adhesive members of Comparative Examples 1 to 4 have lower adhesive reliability than those of Examples 1 to 4 at both room temperature and high temperature. For example, it is seen that the adhesive members obtained after photo-curing the resin compositions of Comparative Examples to 4 had a calculated fracture energy of 100 kJ/m³ or less, resulting in lower durability and impact resistance than those of Examples 1 to 4. For example, it is seen that the adhesive members obtained after photo-curing the resin compositions of Comparative Examples 1 to 4 fail to satisfy the desired range for storage modulus and loss tangent at −25° C. and 25° C., resulting in poorer flexibility and adhesive strength than those of Examples 1 to 4.

Accordingly, the adhesive members formed by photo-curing the resin compositions according to one or more embodiments may exhibit excellent adhesive properties, durability, impact resistance, and flexibility. For example, an electronic device according to one or more embodiments includes the adhesive member formed form the resin composition according to one or more embodiments, and may thus exhibit excellent or suitable reliability.

A resin composition according to one or more embodiments includes a urethane (meth)acrylate oligomer, and a polymer including a unit derived from a cyclodextrin that does not have a (meth)acryloyl group, and may thus exhibit excellent or suitable adhesive properties, durability, impact resistance, and flexibility.

An adhesive member according to one or more embodiments may exhibit high adhesive reliability.

An electronic device according to one or more embodiments includes a polymer derived from the resin composition according to one or more embodiments, and may thus exhibit excellent or suitable reliability and excellent or suitable display quality.

The description above has been made with reference to embodiments of the present disclosure, but those skilled or of ordinary skill in the art may understand that various suitable modifications and changes may be made to the present disclosure insofar as such modifications and changes do not depart from the spirit and technical scope of the present disclosure set forth in the claims to be described later.

Therefore, the technical scope of the present disclosure is not to be limited to the contents stated in the detailed description of the specification, but should be determined by the claims and their equivalents.

What is claimed is:

1. A resin composition comprising:
a urethane (meth)acrylate oligomer; and
a polymer including a unit derived from a cyclodextrin that does not have a (meth)acryloyl group.

2. The resin composition of claim 1, wherein the polymer comprises a cyclodextrin that does not have a (meth)acryloyl group or a derivative thereof.

3. The resin composition of claim 2, wherein the cyclodextrin derivative that does not have a (meth)acryloyl group comprises at least one selected from among hydroxypropyl cyclodextrin, hydroxyethyl cyclodextrin, methylated cyclodextrin, ethylated cyclodextrin, or benzylated cyclodextrin.

4. The resin composition of claim 1, wherein the polymer is a polyurethane in which a cyclodextrin derivative that does not have a (meth)acryloyl group is covalently bonded.

5. The resin composition of claim 1, wherein the polymer has a weight average molecular weight (Mw) of 10,000 g/mol to 100,000 g/mol.

6. The resin composition of claim 1, wherein the polymer is provided in an amount of 2 wt % to 20 wt % with respect to a total weight of the resin composition.

7. The resin composition of claim 1, wherein the urethane (meth)acrylate oligomer has a weight average molecular weight of 5,000 g/mol to 30,000 g/mol.

8. The resin composition of claim 1, wherein the urethane (meth)acrylate oligomer is provided in an amount of 2 wt % to 20 wt % with respect to a total weight of the resin composition.

9. The resin composition of claim 1, wherein a weight ratio of the urethane (meth)acrylate oligomer and the polymer is 1:0.2 to 1:2.5.

10. The resin composition of claim 1, further comprising a monofunctional (meth)acrylate monomer.

11. The resin composition of claim 10, wherein the monofunctional (meth)acrylate monomer comprises at least one selected from among 4-hydroxybutyl acrylate, 2-methoxyethyl acrylate, 2-hydroxyethyl acrylate, 2-hydroxypropyl acrylate, 2-hydroxybutyl acrylate, tetrahydrofurfuryl acrylate, isobornyl acrylate, 2-ethylhexyl acrylate, n-butyl acrylate, t-butyl acrylate, isodecyl acrylate, lauryl acrylate, stearyl acrylate, or isostearyl acrylate.

12. The resin composition of claim 10, wherein the monofunctional (meth)acrylate monomer is provided in an amount of 60 wt % to 95 wt % with respect to a total weight of the resin composition.

13. The resin composition of claim 1, further comprising a photopolymerization initiator.

14. The resin composition of claim 13, wherein the photopolymerization initiator comprises at least one of bis(2,4,6-trimethylbenzoyl)phenyl phosphine oxide or α-hydroxy alkyl phenone.

15. An adhesive member comprising a polymer derived from a resin composition,
wherein the resin composition includes:
a urethane (meth)acrylate oligomer; and
a polymer including a unit derived from a cyclodextrin that does not have a (meth)acryloyl group.

16. The adhesive member of claim 15, comprising:
a 180° peel strength of 600 gf/25 mm or greater on a glass substrate measured at 25° C., and
a 180° peel strength of 150 gf/25 mm or greater on a glass substrate measured at 60° C.

17. An electronic apparatus comprising:
a display apparatus configured to provide images; and
at least one adhesive member included in the display apparatus and including a polymer derived from a resin composition,
wherein the resin composition includes:
a urethane (meth)acrylate oligomer; and
a polymer including a unit derived from a cyclodextrin that does not have a (meth)acryloyl group.

18. The electronic apparatus of claim 17, wherein the display apparatus further comprises a display panel configured to display images and a window on the display panel, and
the adhesive member is between the display panel and the window.

19. The electronic apparatus of claim 18, wherein the window comprises a base layer and a printing layer between the adhesive member and the base layer, and
the resin composition provided on one surface of the display panel or one surface of the window is cured by light passing through the printing layer for irradiation to form the adhesive member.

20. The electronic apparatus of claim 17, wherein the electronic apparatus is a television, a monitor, an outdoor billboard, a personal computer, a laptop computer, a personal digital terminal, an in-vehicle device, a game console, a smartphone, a tablet, a smartwatch, or a camera.
